(19) United States
(12) Patent Application Publication
(10) Pub. No.: US 2011/0020966 A1
(43) Pub. Date: Jan. 27, 2011

(54) METHOD FOR PROCESSING SILICON SUBSTRATE AND METHOD FOR PRODUCING SUBSTRATE FOR LIQUID EJECTING HEAD

(75) Inventors: Mitsuru Chida, Yokohama-shi (JP); Keiji Edamatsu, Fukushima-shi (JP); Toshiyasu Sakai, Kawasaki-shi (JP); Jun Yamamuro, Yokohama-shi (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 12/839,301

(22) Filed: Jul. 19, 2010

(30) Foreign Application Priority Data
Jul. 23, 2009 (JP) 2009-172126

(51) Int. Cl. H01L 21/306

(52) U.S. Cl. 438/21; 438/733; 257/E21.215

(57) ABSTRACT

A method for processing a silicon substrate includes preparing a first silicon substrate including an etching mask layer including first and second opening portions; forming a first recess in a portion of the silicon substrate corresponding to a region in the first opening portion; etching the silicon substrate by crystal anisotropic etching through the etching mask layer with an etching apparatus and an etchant, the etching proceeding in the first and second opening portions to form a through hole in a position corresponding to the first opening portion and to form a second recess in a position corresponding to the second opening portion; calculating an etching rate of the silicon substrate in terms of the etchant by using the second recess; and determining, by using the calculated etching rate, an etching condition for etching another silicon substrate with the etching apparatus after the etching of the first silicon substrate.

### BACKGROUND OF THE INVENTION

1. Field of the Invention

The present invention relates to a method for processing a silicon substrate and a method for producing a substrate for a liquid ejecting head configured to eject liquid.

2. Description of the Related Art

A liquid ejecting head configured to eject liquid includes a silicon substrate including an energy generating element that generates energy used for ejecting the liquid and a supply port for supplying liquid to the energy generating element, the supply port penetrating through the silicon substrate.

As for a technique for forming such a liquid supply port in a silicon substrate, a technique of subjecting a silicon substrate having a <100> plane orientation to anisotropic etching with an alkaline solution is generally employed. This technique utilizes the difference in dissolution rate between plane orientations to the alkaline solution. Specifically, the etching proceeds so that a <111> plane being dissolved at an extremely low rate remains.

According to existing anisotropic etching techniques for silicon, for example, as illustrated in FIG. 5, when a silicon substrate 51 having a thickness T is processed so as to be penetrated, a surface that is firstly etched geometrically needs to have a width of at least (2T/tan 54.7°). This hampers, for example, reduction of the size of chips and processing of chips in later steps such as a die bonding step.

To overcome such a problem, US2007/0212890 discloses a method in which the width of a surface being firstly etched is decreased with a leading hole.

U.S. Pat. No. 3,416,468 discloses a production method in which a silicon substrate is subjected to a heat treatment and then to anisotropic etching. In this document, an ink supply port having a sectional shape is formed in which, from the back surface of the silicon substrate to a desired height, <111> are formed in directions in which the processing width increases; and, beyond the desired height, <111> are formed in directions in which the processing width decreases. Hereafter, such a sectional shape is referred to as a “barrel shape”.

U.S. Pat. No. 6,805,432 discloses a method for forming an ink supply port having a barrel shape by performing dry etching and subsequently performing anisotropic etching.

To accurately form an ink supply port by such a method, an etching rate needs to be strictly controlled in crystal anisotropic etching.

Furthermore, to accurately control an etching rate, it has been necessary to measure a depth rate by performing crystal anisotropic etching with a dummy substrate prepared for the measurement, the crystal anisotropic etching being performed separately from crystal anisotropic etching for product substrates. Thus, there are cases where production processes involve a heavy load and a waste of time.

### SUMMARY OF THE INVENTION

The present invention provides a method for processing a silicon substrate by which an etching rate can be strictly controlled while processing treatments are performed. The present invention also provides a method for producing a substrate for a liquid ejecting head, the method employing the method for processing a silicon substrate and providing a high production efficiency.

A method for processing a silicon substrate according to an aspect of the present invention includes:

preparing a first silicon substrate including an etching mask layer on one surface of the first silicon substrate, the etching mask layer including a first opening portion and a second opening portion;

forming a first recess in a portion of the first silicon substrate, the portion corresponding to a region in the first opening portion, the first recess being recessed toward another surface of the first silicon substrate opposite the one surface;

etching the first silicon substrate by a crystal anisotropic etching technique in which the etching mask layer is used as a mask and an etching apparatus and an etchant are used, the etching proceeding in the first opening portion and the second opening portion in a direction from the one surface to the other surface, to form a through hole penetrating between the one surface and the other surface and being in a position corresponding to the first opening portion in the first silicon substrate and to form a second recess being in a position corresponding to the second opening portion in the first silicon substrate and being recessed toward the other surface;

calculating an etching rate of the first silicon substrate in terms of the etchant by using the second recess; and

determining, by using the calculated etching rate, an etching condition for etching another silicon substrate with the etching apparatus after the etching of the first silicon substrate.

By performing a method for processing a silicon substrate according to the present invention, an etching rate can be strictly controlled while crystal anisotropic etching treatments are performed. Thus, through holes can be more stably formed in silicon substrates.

Further features of the present invention will become apparent from the following description of exemplary embodiments with reference to the attached drawings.

### BRIEF DESCRIPTION OF THE DRAWINGS

FIGS. 1A to 1C are schematic views for illustrating steps according to an embodiment of the present invention.

FIGS. 2A to 2D are schematic sectional views illustrating states in which crystal anisotropic etching proceeds according to an embodiment of the present invention.

FIGS. 3A to 3H are schematic views illustrating steps for producing inkjet heads according to an embodiment of the present invention.

FIG. 4 is a plan view illustrating a first opening portion in which a <100> plane is exposed in a step of forming leading holes (FIG. 3F) according to an embodiment of the present invention.

FIG. 5 is a schematic sectional view illustrating an example of existing ink supply ports.

FIG. 6 is a schematic perspective view of an inkjet recording head a portion of which is cut away for illustration.

FIG. 7 is a schematic sectional view illustrating a configuration according to another embodiment of the present invention.

FIG. 8 is a schematic view illustrating an example in which a mask pattern for measuring an etching rate is disposed.

### DESCRIPTION OF THE EMBODIMENTS

In general, liquid ejecting head devices are formed by forming a channel forming layer and ejection orifices on a silicon wafer (having a diameter of, for example, 6 inches) on which ejection energy generating elements are formed. Thus, a plurality of liquid ejecting head devices are formed on a single wafer. Such liquid ejecting head devices correspond to product chips.

An embodiment of the present invention provides a method for processing a plurality of wafers that are silicon substrates for liquid ejecting head devices. In the embodiment, a mask layer for measuring an etching rate is formed in a portion of the back surface of each wafer that is a silicon substrate for liquid ejecting head devices, the portion being in a region other than a region where the liquid ejecting head devices are formed. When a crystal anisotropic etching treatment is performed for forming liquid ejection orifices in a later step, an etched space is formed in a second opening portion formed in the mask layer for measuring an etching rate. The state of an etchant is determined on the basis of the etched space and conditions of the crystal anisotropic etching treatment for the next lot can be adjusted.

For example, an etchant used for crystal anisotropic wet etching is generally used for a plurality of lots as long as a step yield factor is a predetermined reference value or higher. However, silicon leaches into such an etchant and hence there are cases where an etching rate varies from lot to lot. According to an embodiment of the present invention, by forming a second opening portion for measuring an etching rate in an etching mask, the state of an etchant can be determined while a product substrate is subjected to crystal anisotropic etching to form liquid supply ports. In consideration of the result of the determination, treatment conditions of crystal anisotropic etching for the next lot can be selected. Accordingly, the etching rate can be controlled while crystal anisotropic etching is performed. Thus, liquid supply ports can be formed more stably. Furthermore, according to the embodiment, a step of measuring an etching rate with a dummy substrate prepared for the measurement is no longer necessary. Thus, production costs and production time can be reduced. In commercial-scale production, a batch process in which a plurality of wafers are simultaneously treated is generally employed. In this case, the second opening portion for measuring an etching rate may be formed in all the wafers to be treated in one batch process or may be formed only in one or more wafers to be treated in one batch process. This can be appropriately determined in accordance with conditions such as the number of wafers treated in one batch process or the size of an etching apparatus.

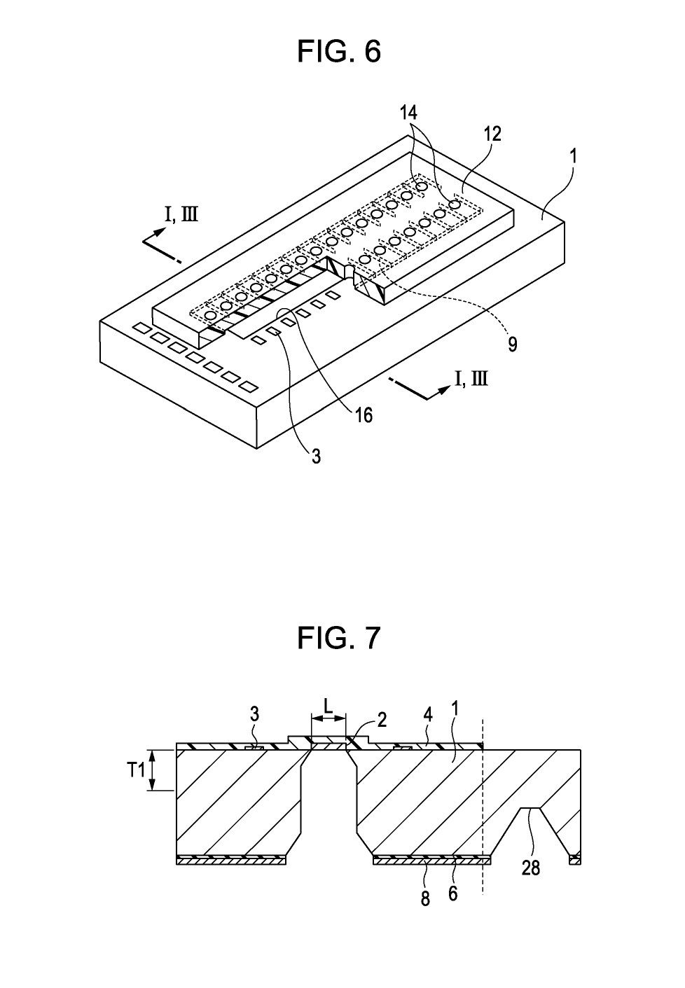

FIG. 6 is a schematic perspective view of an inkjet recording head serving as an example. Note that the present invention is not restricted to inkjet recording heads.

The inkjet recording head illustrated in FIG. 6 includes a silicon substrate 1 on which two rows of ejection energy generating elements 3 are formed at a predetermined pitch. A polyetheramide layer (not shown) serving as an adhesive layer is formed on the silicon substrate 1. Furthermore, channel walls 9 and ink ejection orifices 14 positioned above the ejection energy generating elements 3 are also formed with a photosensitive resin coating 12 on the silicon substrate 1. The photosensitive resin coating 12 constitutes ink channels extending from an ink supply port 16 to the ink ejection orifices 14. The ink supply port 16 formed by subjecting the back surface of the silicon substrate 1 to crystal anisotropic etching through SiO₂ film serving as a mask is positioned between the two rows of the ejection energy generating elements 3. The inkjet recording head is configured to perform recording in the following manner. Ink (liquid) is filled into ink channels through the ink supply port 16. A pressure generated by the ejection energy generating elements 3 is applied to the ink (liquid). As a result, ink droplets are ejected through the ink ejection orifices 14 to adhere to a recording medium.

Such an inkjet recording head can be incorporated into printers, copiers, facsimiles including communication systems, apparatuses including printer units such as word processors, and industrial recording apparatuses in which various processing units are integrated. By using such an inkjet recording head, recording can be performed on various recording media such as papers, threads, fibers, leathers, metals, plastics, glasses, woods, and ceramics. Note that, the term “record” in the present specification means not only to form informative images such as letters or drawings on recording media but also to form non-informative images such as patterns on recording media.

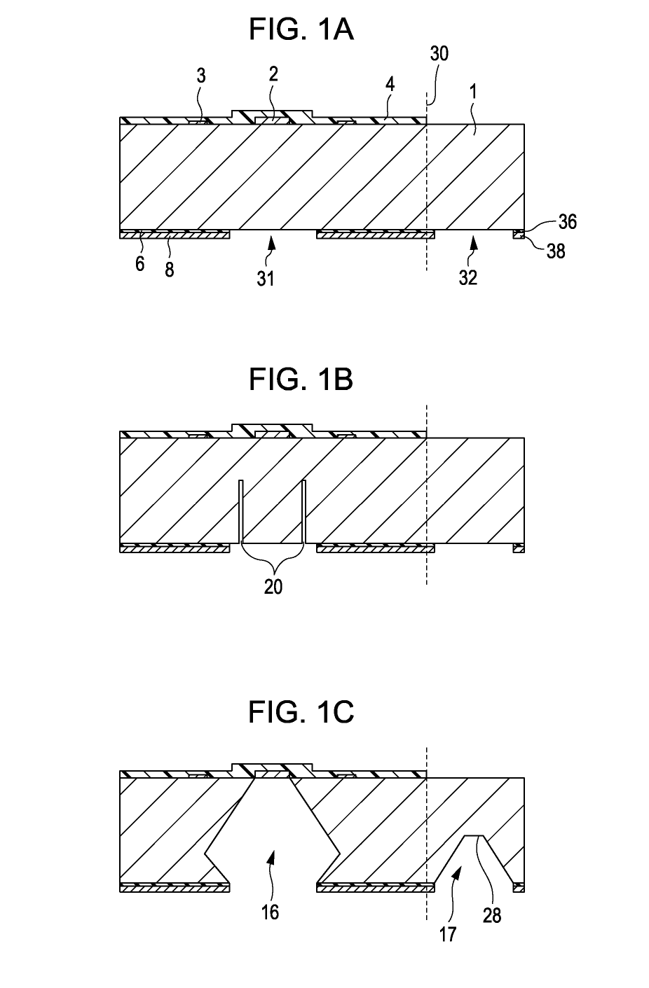

Hereinafter, an embodiment of the present invention will be described with reference to FIGS. 1A to 1C.

In the description below, a silicon substrate for an inkjet recording head will be described as an example to which the present invention is applied. However, the scope to which the present invention is applied is not restricted to this example. The present invention can be applied not only to silicon substrates for inkjet heads but also to production of biochips and methods for producing silicon substrates for liquid ejecting heads used for printing electronic circuits. Such liquid ejecting heads include, in addition to inkjet recording heads, for example, heads for producing color filters.

FIGS. 1A to 1C are sectional views for illustrating steps in a method for processing a silicon substrate according to an embodiment of the present invention. FIGS. 1A to 1C illustrate sections taken along line I-I in FIG. 6.

Referring to FIG. 1A, a SiO₂ film 6 and an etching mask layer 8 are formed on the back surface of the silicon substrate 1 (crystal orientation: <100>). In FIG. 1A, functions of the mask layer are divided with respect to a dotted line 30 serving as a boundary. The left portion (in FIG. 1A) of the mask layer is used as the etching mask layer 8 for the liquid supply port. The right portion (in FIG. 1A) of the mask layer is used as a mask layer 38 for measuring an etching rate. In the present embodiment, the etching mask layer (serving as the etching mask layer 8) for a liquid supply port and the mask layer for measuring an etching rate can be formed as a layer composed of the same material by, for example, a spin coating method. A first opening portion 31 providing a surface that is firstly etched by crystal anisotropic etching performed in a later step is formed in the etching mask layer. A second opening portion 32 is formed in the mask layer 38 for measuring an etching rate. The first opening portion 31 and the second opening portion 32 can be simultaneously formed by a photolithographic technique or the like. The second opening portion 32 is formed in a region other than a region for liquid ejecting head devices. In general, at least one second opening portion 32 is formed, in a wafer, in a region from which devices are not provided. In the present embodiment, blind holes serving as leading holes for crystal anisotropic etching are formed in the first opening portion 31. The second opening portion 32 can also be used as an alignment mark in the formation of the blind holes. Alternatively, the second opening portion 32 may be formed as an alignment mark in a region from which devices can be provided in a wafer.

As illustrated in FIG. 1A, the ejection energy generating elements 3, a sacrificial layer 2, and a passivation layer 4 are formed on the front surface of the silicon substrate.

As illustrated in FIG. 1B, blind holes 20 that are recesses and serve as leading holes are subsequently formed in the first opening portion from the back surface of the silicon substrate. For example, as illustrated in FIG. 1B, at least two leading holes can be formed in a section of the silicon substrate. At least two rows of the blind holes can be formed both in the transverse direction and in the longitudinal direction of the first opening portion so as to be symmetric with respect to the center of the first opening portion. By forming such blind holes, the opening width of the liquid supply port can be decreased. The section of the liquid supply port formed has a barrel shape.

As illustrated in FIG. 1C, crystal anisotropic etching is subsequently performed from the back surface of the silicon substrate to the sacrificial layer. Thus, the ink supply port (liquid supply port) 16 is formed. At this time, the anisotropic etching also proceeds in the second opening portion 32 and, as a result, an etched space 17 that is a recess is formed. The reference numeral 28 denotes a (100) plane.

As described above, in the present embodiment, a mask layer for measuring an etching rate having the second opening portion 32 is formed in a region other than a region for liquid ejecting head devices; and crystal anisotropic etching is performed and the etching proceeds in the second opening portion 32 to form the etched space 17. The etching rate is calculated on the basis of the etched space and etching conditions of the next lot are determined on the basis of the calculated etching rate.

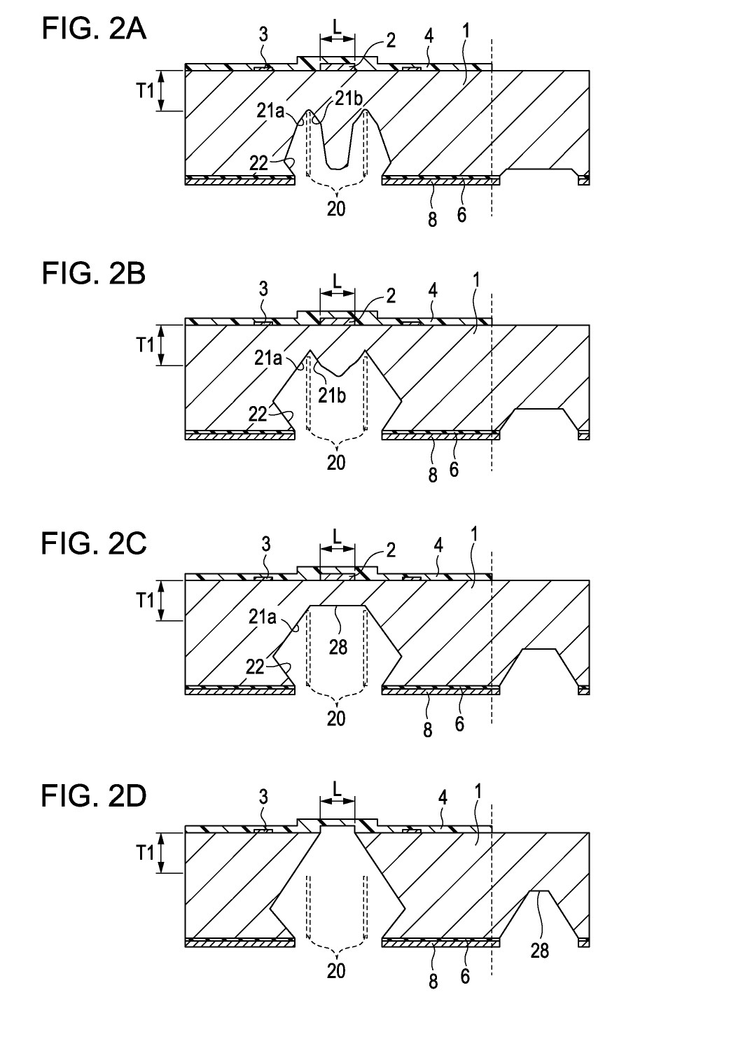

FIGS. 2A to 2D schematically illustrate an example of states in which crystal anisotropic etching proceeds in a silicon substrate in a case where leading holes as illustrated in FIG. 1B are formed. Although a case where an ink supply port is formed will be described below, the present invention is not restricted to this case.

While <111> (21a and 21b) are formed from the tips of the leading holes, in directions in which the processing width decreases toward the front surface of the silicon substrate, the silicon substrate is etched from the inside of the leading holes in a direction perpendicular to the thickness direction. In the first opening portion in the back surface, <111> (22) are formed in directions in which the processing width increases toward the front surface of the silicon substrate. In the second opening portion, <111> planes are formed in directions in which the processing width decreases toward the front surface of the silicon substrate (FIG. 2A).

As the etching proceeds, in the first opening portion, the <111> (21b) of the two leading holes are brought in contact with each other and the etching further proceeds from the vertex formed between the <111> (21b) toward the front surface. In the two leading holes, the <111> (21a) on the external sides and the <111> (22) extending from the opening portion in the back surface intersect and the etching appears not to proceed in a direction perpendicular to the thickness direction. In the second opening portion, the etching continues to proceed in directions in which the processing width decreases (FIG. 2B).

When the etching further proceeds, in the first opening portion, <100> (28) is formed between the two leading holes (FIG. 2C). This <100> (28) is moved toward the front surface of the silicon substrate as the etching proceeds. When the <100> (28) ultimately reaches the sacrificial layer, the crystal anisotropic etching is complete. At this time, the crystal anisotropic etching is also complete in the second opening portion in which a <100> plane is exposed (FIG. 2D).

In the above-described method for forming an ink supply port, the positions of the <111> (22 and 21a) formed in the first opening portion are determined by the leading holes. In the second opening portion, the positions of the <111> planes formed in directions in which the processing width decreases are also determined by the position in which the crystal orientation <100> plane is exposed by crystal anisotropic etching.

As described above, the mask layer for measuring an etching rate having the second opening portion is formed, in the back surface of the silicon substrate, in a region other than a region where liquid ejecting head devices are formed. The shape of the second opening portion is not particularly restricted as long as an etching rate can be measured. For example, the second opening portion may have a quadrangular shape such as a square shape or a rectangular shape. In the etched space in the second opening portion, the surface constituting the top surface of the etched space (the surface formed close to the front surface of the silicon substrate) upon the completion of crystal anisotropic etching has a <100> plane.

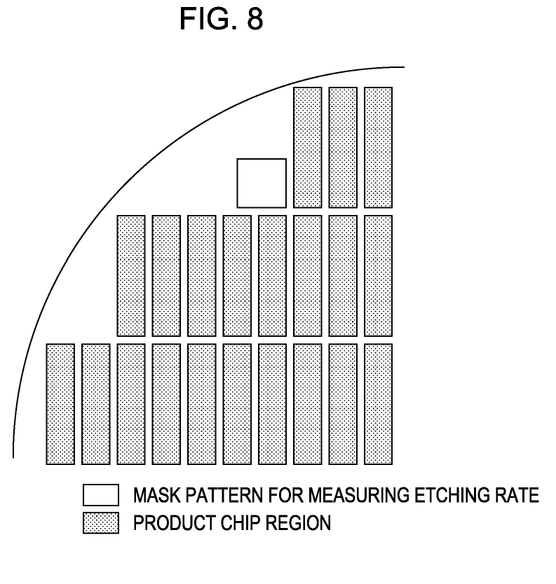

For example, as illustrated in FIG. 8, a mask pattern for measuring an etching rate can be provided in a marginal portion in which product chips are not allocated, in the circumferential portion of a wafer.

For example, when the second opening portion has a rectangular shape, a transverse width Y of the second opening portion for forming the ink supply port can satisfy the following formula:

((S×R)/Tan 54.7°)×2<Y

where S represents the period for which crystal anisotropic etching is performed; and R represents an etching rate.

Specifically, when the width Y of the second opening portion is less than ((S×R)/Tan 54.7°)×2, <111> planes extending from the back surface of a silicon substrate in directions in which the processing width decreases intersect in a V shape during a crystal anisotropic etching treatment. Thus, the etching rate cannot be measured. Accordingly, when the width Y of the second opening portion is more than ((S×R)/Tan 54.7°)×2, the etching rate can be measured.

### Example 1

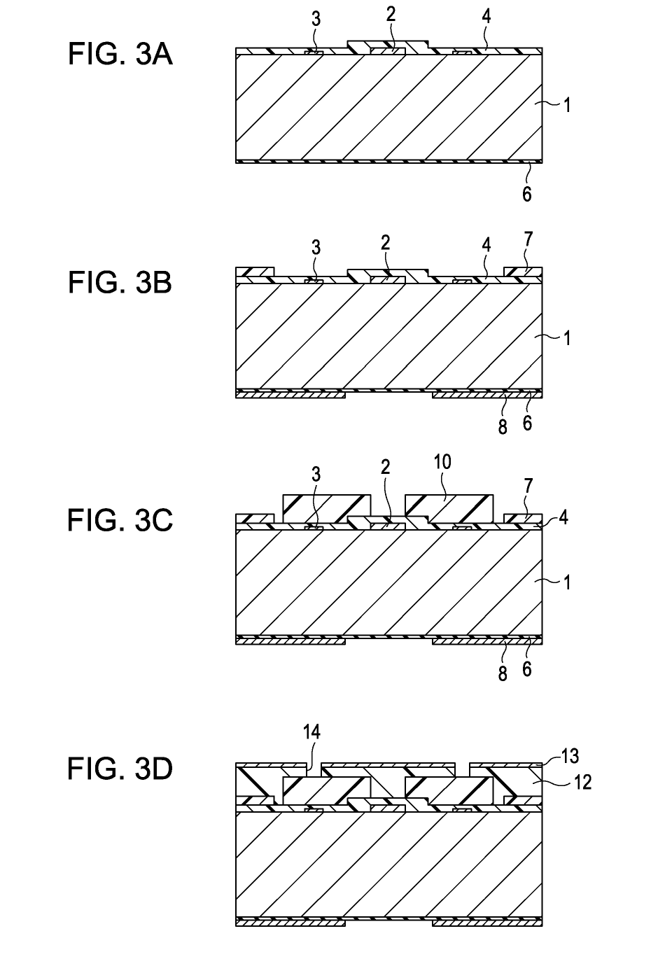

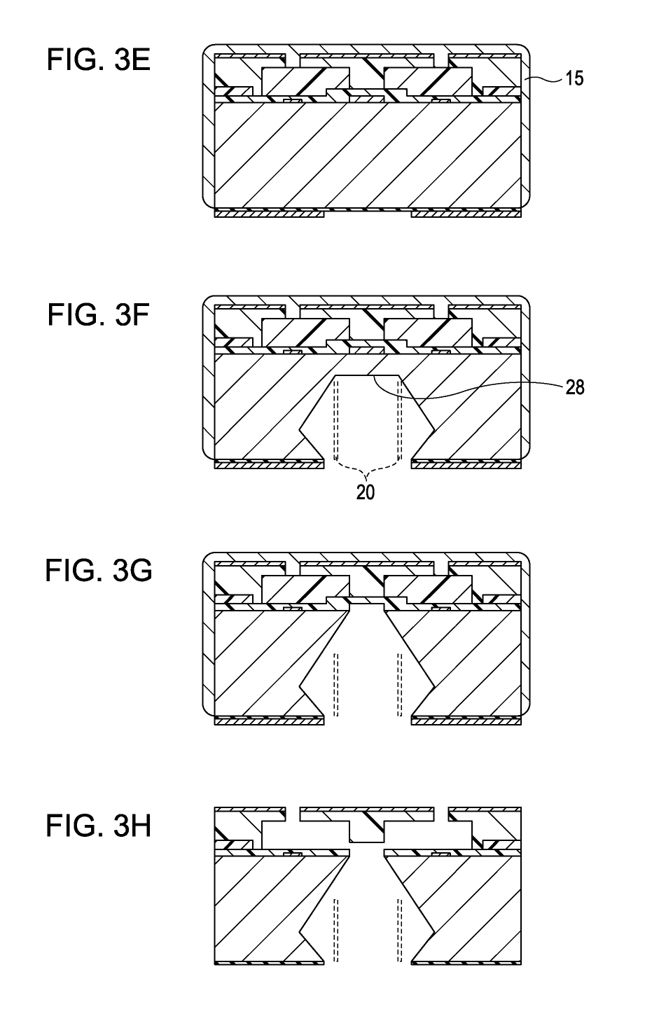

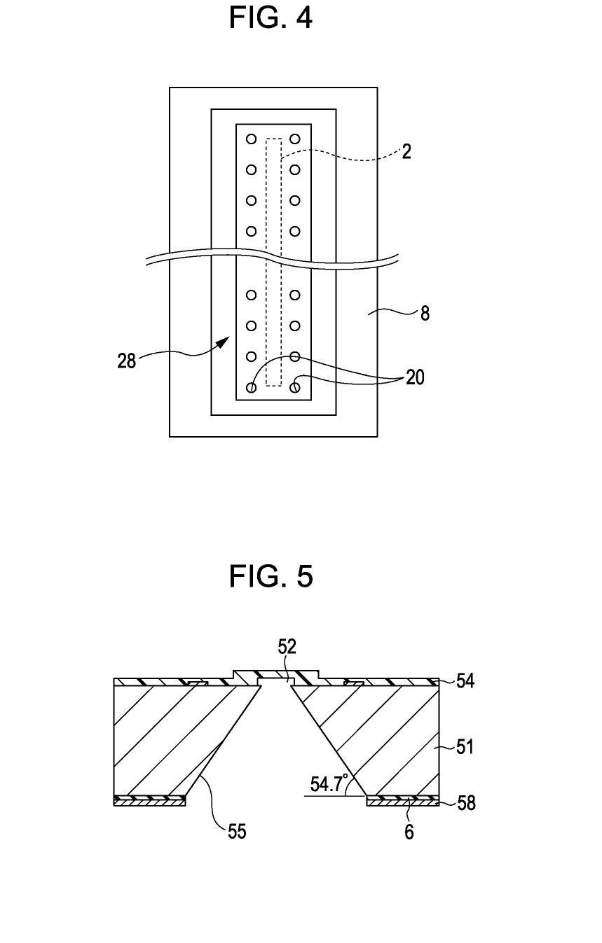

Hereinafter, an embodiment of the present invention will be described in detail with reference to FIGS. 3A to 3H. However, the present invention is not restricted to the embodiment below. The present invention can also be applied to other techniques that are encompassed in the concept of the present invention described in Claims.

FIGS. 3A to 3H are sections taken along line III-III in FIG. 6. FIGS. 3A to 3H are schematic sectional views illustrating basic production steps in a method for processing a silicon substrate according to an embodiment of the present invention.

Referring to FIG. 3A, the plurality of ejection energy generating elements 3 such as heat generating resistors are provided on the substrate 1. The entire back surface of the substrate 1 is covered with the SiO₂ film 6. The sacrificial layer 2 is provided on the front surface of the silicon substrate for the purpose of accurately forming the front surface opening of the ink supply port (liquid supply port). The passivation layer 4 is formed on the silicon substrate and the sacrificial layer.

The sacrificial layer can be etched with an etchant (alkaline solution) for silicon substrates. The sacrificial layer is formed of, for example, poly-Si; or a metal or an alloy that is etched at a high etching rate such as aluminum, aluminum-silicon, aluminum-copper, or aluminum-silicon-copper.

As for the passivation layer 4, after the sacrificial layer is etched by crystal anisotropic etching in a later step, the etching with an etchant does not proceed in the passivation layer 4, that is, the passivation layer 4 is resistant to the etching. The passivation layer is formed of, for example, silicon oxide or silicon nitride. At this time, the passivation layer may be disposed on the back surfaces of the ejection energy generating elements to serve as a thermal storage layer. Alternatively, the passivation layer may be disposed so as to overlap the ejection energy generating elements to serve as a protective layer. Note that wiring of the ejection energy generating elements (heaters) and semiconductor elements for driving the heaters are not illustrated in FIGS. 3A to 3H.

As illustrated in FIG. 3B, the etching mask layer 8 is subsequently formed by applying, for example, a polyetheramide resin to the back surface of the silicon substrate 1 and subjecting the applied polyetheramide resin to a baking treatment. For patterning the etching mask layer 8, a positive resist is applied to the etching mask layer 8 by spin coating or the like, exposed, and developed. The etching mask layer 8 is patterned through the positive resist by dry etching or the like. The positive resist is stripped. Thus, the first opening portion is formed in the etching mask layer 8. The first opening portion provides a surface that is firstly etched by crystal anisotropic etching performed in a later step.

For example, a polyetheramide resin is applied to the front surface of the passivation layer and cured. A positive resist is applied to a polyetheramide resin 7 by spin coating or the like, exposed, and developed. The polyetheramide resin 7 is patterned through the positive resist by dry etching or the like. The positive resist is stripped.

As illustrated in FIG. 3C, a positive resist is subsequently patterned on the front surface of the substrate to form mold materials 10 that will provide ink channels (liquid channels).

As illustrated in FIG. 3D, the photosensitive resin coating 12 is subsequently formed on the mold materials 10 by spin coating or the like. Water repellent members 13 are formed on the photosensitive resin coating 12 by, for example, laminating a dry film. The ink ejection orifices 14 are formed by exposing the photosensitive resin coating 12 to ultraviolet rays, Deep UV rays, or the like and developing the photosensitive resin coating 12.

As illustrated in FIG. 3E, the front surface and the side surfaces of the substrate 1 on which the mold materials 10, the photosensitive resin coating 12, and the like are formed are subsequently coated by spin coating or the like to be covered by a protective member 15.

As illustrated in FIG. 3F, leading holes are formed in the first opening portion and the ink supply port is then formed by crystal anisotropic etching. At this time, the SiO₂ film 6 in the first opening portion on the back surface of the silicon substrate is removed through the etching mask layer 8 serving as a mask. Then, the blind holes 20 serving as the leading holes are formed so as to extend from the back surface of the silicon substrate 1 by laser processing. Etching is then performed from the back surface of the silicon substrate with an anisotropic etchant such as a tetramethyl ammonium hydroxide (TMAH) solution. Thus, the ink supply port extending to the sacrificial layer is formed (FIG. 3G). In this etching, the etching proceeds as illustrated in FIGS. 2A to 2D. <111> formed from the tips of the leading holes and formed at 54.7° with respect to the back surface reach the sacrificial layer. The sacrificial layer is isotropically etched by an etchant. The top end of the ink supply port has a shape corresponding to the shape of the sacrificial layer. The ink supply port is formed so as to have a section having a barrel shape constituted by <111> planes.

At this time, the crystal anisotropic etching also proceeds in the second opening portion for measuring an etching rate, the second opening portion being formed in the back surface of the silicon substrate (refer to FIGS. 2A to 2D). In the second opening portion, the blind holes 20 formed in the first opening portion are not formed. Accordingly, in the second opening portion, the etching proceeds from the back surface of the silicon substrate. The etching rate is calculated from the relationship between the depth of the etched space formed at this time and the etching period. The calculated result is used as feedback for the calculation of the treatment period of crystal anisotropic etching for the next lot. By repeating such a feedback process, ink supply ports can be constantly formed with stability. In addition to the adjustment of the treatment period of crystal anisotropic etching, the composition of an etchant may also be adjusted.

For example, when the measurement result of an etching rate is defined as R (distance/period in etching in the direction of a <100> plane), the thickness of a wafer to be subsequently etched is defined as T, and the depth of the blind holes is defined as H, etching period S for which the etching region reaches the sacrificial layer from the tips of the blind holes is represented by (T−H)/R=S in the wafer to be subsequently etched.

Furthermore, by exposing a <111> plane, the effect of suppressing leaching of Si into ink (liquid) flowing through the ink supply port can be expected.

As illustrated in FIG. 3H, a portion of the passivation layer 4 is subsequently removed by dry etching. The etching mask layer 8 and the protective member 15 are then removed. The mold materials 10 are then dissolved and removed through the ink ejection orifices (liquid ejection orifices) 14 and the ink supply port 16. Thus, the ink channels are formed.

As a result of the above-described steps, the substrate 1 in which nozzle portions are formed is provided. The substrate 1 is then cut and divided into chips with a dicing saw or the like. To drive the ejection energy generating elements 3, electrical bonding is performed. Then, chip tank members for supplying ink are connected to the chips. Thus, inkjet recording heads are provided.

In FIGS. 3A to 3H, a substrate having a thickness of 600 μm is used as an example. However, the present invention is also applicable to substrates having a thickness smaller or larger than 600 μm. In this case, the present invention can be readily applied by changing the depth of the leading holes and dimensions of the opening portions.

Furthermore, in a case where an ink supply port having a shape illustrated in FIG. 7 is formed by forming leading holes and then performing crystal anisotropic etching, to accurately control the anisotropic etching rate, an embodiment according to the present invention employing a mask layer for measuring an etching rate can also be applied.

In the above description, inkjet recording heads have been used as examples to which the present invention is applied. However, the scope to which the present invention is applied is not restricted to inkjet recording heads. The present invention can also be applied to, for example, biochips and liquid ejecting heads used for printing electronic circuits.

Such a liquid ejecting head can be incorporated into facsimiles, apparatuses including printer units such as word processors, and industrial recording apparatuses in which various processing units are integrated. For example, such a liquid ejecting head can be applied to production of biochips, printing of electronic circuits, and spraying of a medicament.

By using such a liquid ejecting head, recording can be performed on various recording media such as papers, threads, fibers, textiles, leathers, metals, plastics, glasses, woods, and ceramics. Note that, the term “record” in the present specification means not only to form informative images such as letters or drawings on recording media but also to form non-informative images such as patterns on recording media.

In addition, the term “liquid” should be construed broadly to include liquids that are used for forming images, designs, patterns, or the like by being applied to recording media; that are used for processing recording media; and that are used for subjecting ink or recording media to treatment. Here, the treatment for ink or recording media is, for example, enhancement of fixing properties of ink by solidifying or insolubilizing coloring materials in the ink to be provided on recording media; enhancement of recording quality or color development; or enhancement of the durability of images.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-172126 filed Jul. 23, 2009, which is hereby incorporated by reference herein in its entirety.

What is claimed is:

1. A method for processing a silicon substrate, the method comprising:
preparing a first silicon substrate including an etching mask layer on one surface of the first silicon substrate, the etching mask layer including a first opening portion and a second opening portion;
forming a first recess in a portion of the first silicon substrate, the portion corresponding to a region in the first opening portion, the first recess being recessed toward another surface of the first silicon substrate opposite the one surface;
etching the first silicon substrate by a crystal anisotropic etching technique in which the etching mask layer is used as a mask and an etching apparatus and an etchant are used, the etching proceeding in the first opening portion and the second opening portion in a direction from the one surface to the other surface, to form a through hole penetrating between the one surface and the other surface and being in a position corresponding to the first opening portion in the first silicon substrate and to form a second recess being in a position corresponding to the second opening portion in the first silicon substrate and being recessed toward the other surface;
calculating an etching rate of the first silicon substrate in terms of the etchant by using the second recess; and
determining, by using the calculated etching rate, an etching condition for etching another silicon substrate with the etching apparatus after the etching of the first silicon substrate.

2. The method according to claim 1, wherein, in the calculation of the etching rate of the first silicon substrate, the etching rate of the first silicon substrate in a thickness direction of the first silicon substrate is calculated from a distance between a bottom portion of the second recess and the one surface and a period for which the first silicon substrate is etched.

3. The method according to claim 1, wherein the first recess is formed in the first silicon substrate by processing the first silicon substrate with laser.

4. The method according to claim 1, wherein the first recess is formed in the first silicon substrate by processing the first silicon substrate by dry etching.

5. The method according to claim 1, wherein the etching condition is a concentration of the etchant used for the etching.

6. The method according to claim 1, wherein the etching condition is a period for which the etching is performed.

7. The method according to claim 1, wherein, after the etching of the first silicon substrate, the etching condition for etching another silicon substrate with the etching apparatus and the etchant is determined by using the calculated etching rate.

8. A method for producing a substrate for a liquid ejecting head, the method comprising:
preparing a first silicon substrate including an etching mask layer on one surface of the first silicon substrate and an energy generating element on another surface of the first silicon substrate opposite the one surface, the etching mask layer including a first opening portion and a second opening portion, the energy generating element generating energy used for ejecting liquid;
forming a first recess in a portion of the first silicon substrate, the portion corresponding to a region in the first opening portion, the first recess being recessed toward the other surface opposite the one surface;
etching the first silicon substrate by a crystal anisotropic etching technique in which the etching mask layer is used as a mask and an etching apparatus and an etchant are used, the etching proceeding in the first opening portion and the second opening portion in a direction from the one surface to the other surface, to form a through hole for supplying liquid to the energy generating element, the through hole penetrating between the one surface and the other surface and being in a position corresponding to the first opening portion in the first silicon substrate, and to form a second recess being in a position corresponding to the second opening portion in the first silicon substrate and being recessed toward the other surface;
calculating an etching rate of the first silicon substrate in terms of the etchant by using the second recess; and
determining, by using the calculated etching rate, an etching condition for etching another silicon substrate with the etching apparatus after the etching of the first silicon substrate.
